(19) United States
(12) Patent Application Publication
(10) Pub. No.: US 2009/0266408 A1
(43) Pub. Date: Oct. 29, 2009

(54) SOLAR CELL DEVICE WITH MOVABLE REFLECTION UNIT

(75) Inventor: Han-Lung LEE, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/332,323

(22) Filed: Dec. 10, 2008

(30) Foreign Application Priority Data
Apr. 28, 2008 (CN) 200810301342.1

(51) Int. Cl. H01L 31/00

(52) U.S. Cl. 136/252

(57) ABSTRACT

An exemplary solar cell device includes a solar cell, a solar cell board, a reflection unit, an image acquiring unit, a signal processing and control unit and a drive unit. The solar cell is disposed on the solar cell board and has a receiving face. The reflection unit is opposite to the solar cell board and reflects sunlight to the receiving face of the solar cell. The image acquiring unit acquires image data of the sun. The signal processing and control unit receives and processes the image data to obtain a current position of the sun to generate a corresponding work instruction. The drive unit receives the work instruction and drives the reflection unit to a position in which the reflection unit reflects an optimum amount of sunlight to the solar cell board.

### BACKGROUND

1. Technical Field

The invention relates to solar cell devices, and more particularly to a solar cell device for tracking the sun automatically.

2. Description of Related Art

Solar energy is an inexhaustible energy source, which teas been followed with great interest by many people. Solar energy has advantages such as perpetual availability and environmental cleanliness.

Solar cell devices are a popular subject of research in the field of power and energy. Solar cell devices are applied in buildings (such as houses), in vehicles (such as cars), and in all kinds of portable electronic devices, for transforming solar energy into electrical power. When the intensity of solar radiation which illuminates the solar cell device is strong, the output current of the solar cell device is correspondingly large. That is, the solar cell device can provide much electrical energy.

When the solar cell device is installed in a fixed position, it may not efficiently capture solar energy as the position of the sun changes over time. In general, a solar cell device that is movable and can follow the position of the sun is preferred. This issue has received much attention from people who use solar cell devices.

### BRIEF DESCRIPTION OF THE DRAWINGS

FIG. 1 is essentially an isometric view of a solar cell device for tracking the sun automatically in accordance with an exemplary embodiment of the present invention, showing the solar cell device in a first state.

FIG. 2 is similar to FIG. 1, but showing the solar cell device having adjusted to be in a second state.

### DETAILED DESCRIPTION

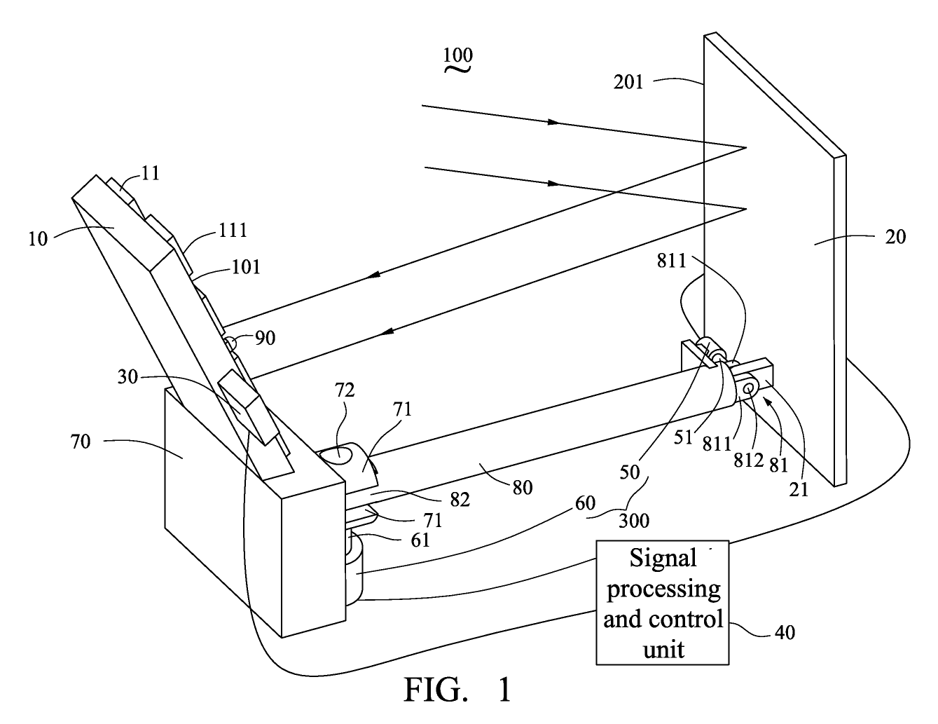

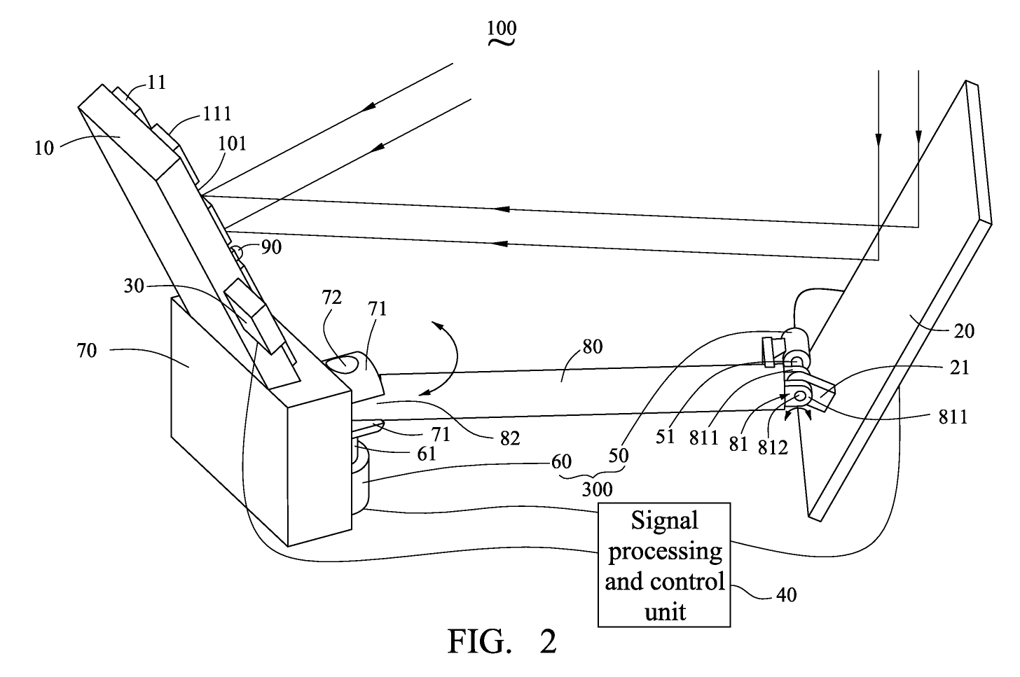

Referring to FIG. 1 and FIG. 2, a solar cell device 100 for tracking the sun automatically according to an exemplary embodiment of the present invention is shown. The solar cell device 100 includes a plurality of solar cells 11, a solar cell board 10, a reflection unit 20, an image acquiring unit 30, a signal processing and control unit 40, a drive unit 300, a base 70, and a connecting member 80. In addition, the image acquiring unit 30, the signal processing and control unit 40 and the drive unit 300 cooperatively form a sun auto tracking module, which is comprised in the solar cell device 100.

The solar cells 11 are disposed on a main surface 101 of the solar cell board 10, and are coupled with each other. Each solar cell 11 has a receiving face 111. The number solar cells 11 employed can be determined according to need. The main surface 101 of the solar cell board 10 corresponds to the reflection unit 20, with the receiving faces 111 of the solar cells 11 being opposite to the reflection unit 20. In the illustrated embodiment, the reflection unit 20 is in the form of a flat reflecting board. The reflection unit 20 has a main body (not labeled), a reflecting face 201, and a connection portion 21 extending from the main body. The reflection unit 20 may have any of various desired shapes, for example, planar or paraboloid.

In this embodiment, the image acquiring unit 30 is disposed on one side of the solar cell board 10, and acquires image data of the sun. For example, the image acquiring unit 30 can be a camera. The camera can be a digital camera, for instance be a charge-coupled device (CCD) camera or a complementary metal oxide semiconductor (CMOS) camera.

The signal processing and control unit 40 is coupled with the image acquiring unit 30, and receives, processes and analyses the image data of the sun to obtain position data of the sun. The signal processing and control unit 40 generates a work instruction according to the position data of the sun, and outputs the work instruction to the drive unit 300 for adjusting a position of the reflection unit 20. A means of connecting the signal processing and control unit 40 and the image acquiring unit 30 may be any suitable means, for example, a Personal System/2 (PS/2) port, a wireless interface, or a Universal Serial Bus (USB) interface. In addition, the signal processing and control unit 40 has an image processing program (software) for processing the image data. When the sunlight reaches the image acquiring unit 30 to form an image thereon, the signal processing and control unit 40 is thereupon able to process the image. The signal processing and control unit 40 determines an elevation angle of the sun and an azimuth of the sun from the center of the image, to acquire a position of the sun.

The drive unit 300 has a first drive element 50 and a second drive element 60, both of which are coupled with the signal processing and control unit 40. The first and second drive elements 50, 60 receive the work instruction for adjusting the position of the reflection unit 20. For example, the drive unit 300 can be a drive motor assembly, or an assembly of a drive motor and a transmission connected with each other. In the illustrated embodiment, the first drive element 50 is a first drive motor, and the second drive element 60 is a second drive motor. If employed, the transmission can be selected according to a desired precision of rotation angles of the reflection unit 20. For example, the transmission may include a parallel axes bevel gear, a worm wheel, a planetary gear, etc. The first drive element 50 has a first output rotor 51 which is oriented in a horizontal direction, and the second drive element 60 has a second output rotor 61 which is oriented in a vertical direction. In the illustrated embodiment, the second drive element 60 is fixed to the base 70.

In this embodiment, the connecting member 80 is in the form of a connecting shaft, and has a first end portion 81 and a second end portion 82. The first end portion 81 is movably connected with the connection portion 21 of the reflection unit 20, and the second end portion 82 is movably connected with the base 70. In particular, the first end portion 81 has two first knuckles 811, which are spaced apart from each other a first predetermined distance. Each first knuckle 811 defines a first assembly hole 812 therein. The connection portion 21 of the reflection unit 20 is disposed between the two first knuckles 811, and the first output rotor 51 is rotatably received in the two first assembly holes 812 and fixed to the connection portion 21.

The base 70 has two second knuckles 71 extending from a main body thereof. The second knuckles 71 are spaced apart from each other a second predetermined distance. Each second knuckle 71 defines a second assembly hole 72 therein. The second end portion 82 of the connecting member 80 is movably disposed between the two second knuckles 71, and the second output rotor 61 is rotatably received in the two second assembly holes 72 and fixed to the second end portion 82.

FIGS. 1 and 2 show the reflection unit 20 of the solar cell device 100 in two different positions. Referring to FIG. 1, the reflection unit 20 is shown in an initial position. At this time, the receiving faces 111 of the solar cells 11 do not directly receive sunlight, and the reflecting face 201 of the reflection unit 20 is positioned for reflecting sunlight to the receiving faces 111 to ensure that the solar cell board 10 receives sunlight.

Referring to FIG. 2, when the position of the sun has changed, the receiving faces 111 of the solar cells 11 receives sunlight directly. The position of the reflection unit 20 is adjusted for reflecting sunlight from the reflecting face 201 of the reflection unit 20 to the solar cell board 10. Thereby, the energy density of operative areas of the receiving faces 111 of the solar cells 11 is increased.

When the image acquiring unit 30 acquires the image data of the sun, the signal processing and control unit 40 receives, processes and analyses the image data to obtain the position data of the sun and generate a corresponding work instruction. The signal processing and control unit 40 then transmits the work instruction to the first drive element 50 and the second drive element 60 for adjusting the position of the reflection unit 20. In the driving of the first drive element 50, the connection portion 21 of the reflection unit 20 rotates along with the first output rotor 51 to adjust an included angle, which is defined between the connection portion 21 of the reflection unit 20 and the receiving faces 111. In other words, the tilt of the reflection unit 20 is adjusted. In the driving of the second drive element 60, the connecting member 80 rotates along with the second output rotor 61 to adjust the angular position of the reflection unit 20 as measured in a horizontal plane relative to a center of the solar cell board 10. In this description, such angular position is called an azimuthal position of the reflection unit 20 relative to the solar cell board 10. Accordingly, the reflection unit 20 is moved to the best position by the first drive element 50 and the second drive element 60, so that the solar cell board 10 receives strong sunlight both directly and by reflection from the reflection unit 20.

Furthermore, referring to FIGS. 1 and 2, the solar cell device 100 further includes a sensing unit 90 such as a sensor, which is disposed on the surface of the solar cell board 10. The sensing unit 90 is connected to the signal processing and control unit 40. When the sensing unit 90 senses that sunlight reflected from the reflection unit 20 to the solar cell board 10 is strongest, the signal processing and control unit 40 controls the drive unit 300 so that the reflection unit 20 stops moving.

The solar cell device 100 automatically tracks the sun in real time via the image acquiring unit 30, and correspondingly moves the reflecting face 201 of the reflection unit 20 to receive sunlight which is strongest and which can be reflected from the reflection unit 20 to the solar cell board 10. The solar cell device 100 ensures that the solar cell board 10 not only receives direct sunlight as the position of the sun changes, but also efficiently receives reflected sunlight as the position of the sun changes.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A solar cell device, comprising:
a solar cell comprising a receiving face;
a solar cell board, the solar cell being disposed on the solar cell board;
a reflection unit opposite to the solar cell board and capable of reflecting sunlight to the receiving face of the solar cell;
an image acquiring unit configured for acquiring image data of the sun;
a signal processing and control unit configured for receiving and processing the image data to obtain a current position of the sun and generate a corresponding work instruction; and
a drive unit configured for receiving the work instruction and driving the reflection unit to a position in which the reflection unit is capable of reflecting an optimum amount of sunlight to the solar cell board.

2. The solar cell device of claim 1, wherein the drive unit further comprises a first drive element and a second drive element, the first drive element is configured for driving the reflection unit to tilt to adjust an included angle defined between the reflection unit and the solar cell board, and the second drive element is configured for driving the reflection unit to rotate to adjust an azimuthal position of the reflection unit relative to the solar cell board.

3. The solar cell device of claim 2, wherein the first drive element includes a first drive motor and has a first output rotor, and the second drive element includes a second drive motor and has a second output rotor.

4. The solar cell device of claim 3, wherein the first output rotor is oriented in a horizontal direction, the second output rotor is oriented in a vertical direction.

5. The solar cell device of claim 4, wherein the reflection unit is fixed to the first output rotor, the solar cell device further comprises a connecting member between the solar cell board and the reflection unit, the connecting member includes a first end portion and a second end portion, the first end portion is movably connected with the reflection unit, and the second end portion is fixed to the second output rotor.

6. The solar cell device of claim 5, wherein the reflection unit is capable of tilting along with rotation of the first output rotor, and the connecting member is capable of rotating along with rotation of the second output rotor to adjust said azimuthal position.

7. The solar cell device of claim 1, wherein the reflection unit is one of substantially planar-shaped and paraboloid-shaped.

8. The solar cell device of claim 1, wherein the image acquiring unit comprises one of a charge coupled device (CCD) camera and a complementary metal oxide semiconductor (CMOS) camera.

9. The solar cell device of claim 1, further comprising a base, wherein the solar cell board is attached to the base.

10. The solar cell device of claim 1, wherein the image acquiring unit, the signal processing and control unit, and the drive unit cooperatively form a sun auto tracking module.

11. A solar cell device, comprising:
a solar cell comprising a receiving face;
a solar cell board, the solar cell being disposed on the solar cell board;
a reflection unit opposite to the solar cell and capable of reflecting sunlight to the receiving face of the solar cell;
an image acquiring unit configured for acquiring image data of the sun;
a signal processing and control unit configured for receiving and processing the image data to obtain a current position of the sun and generate a corresponding work instruction;
a drive unit configured for receiving the work instruction and driving the reflection unit to a position in which the reflection unit is capable of reflecting an optimum amount of sunlight to the solar cell board; and
a sensing unit configured for sensing sunlight, wherein when the sensing unit senses that sunlight reflected from the reflection unit to the solar cell board is the optimum amount, the signal processing and control unit is capable of correspondingly controlling the drive unit to stop driving the reflection unit.

12. The solar cell device of claim 11, wherein the drive unit further comprises a first drive element and a second drive element, the first drive element is configured for driving the reflection unit to tilt to adjust an included angle defined between the reflection unit and the solar cell board, and the second drive element is configured for driving the reflection unit to rotate to adjust an azimuthal position of the reflection unit relative to the solar cell board.

13. The solar cell device of claim 12, wherein the first drive element includes a first drive motor and has a first output rotor, and the second drive element includes a second drive motor and has a second output rotor.

14. The solar cell device of claim 13, wherein the first output rotor is oriented in a horizontal direction, the second output rotor is oriented in a vertical direction.

15. The solar cell device of claim 14, wherein the reflection unit is fixed to the first output rotor, the solar cell device further comprises a connecting member between the solar cell board and the reflection unit, the connecting member includes a first end portion and a second end portion, the first end portion is movably connected with the reflection unit, and the second end portion is fixed to the second output rotor.

16. The solar cell device of claim 15, wherein the reflection unit is capable of tilting along with rotation of the first output rotor, and the connecting member is capable of rotating along with rotation of the second output rotor to adjust said azimuthal position.

17. The solar cell device of claim 11, wherein the reflection unit is one of substantially planar-shaped and paraboloid-shaped.

18. The solar cell device of claim 11, wherein the image acquiring unit comprises one of a charge coupled device (CCD) camera and a complementary metal oxide semiconductor (CMOS) camera.

19. The solar cell device of claim 11, further comprising a base, wherein the solar cell board is attached to the base.

20. The solar cell device of claim 11, wherein the image acquiring unit, the signal processing and control unit, and the drive unit cooperatively form a sun auto tracking module.
